(19) United States
(12) Patent Application Publication
(10) Pub. No.: US 2023/0144564 A1
(43) Pub. Date: May 11, 2023

(54) FOLDING PLATE AND METHOD FOR MANUFACTURING SAME

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 17/912,839

(22) PCT Filed: Mar. 15, 2021
(86) PCT No.: PCT/KR2021/003169

§ 371 Date: Sep. 19, 2022

(30) Foreign Application Priority Data
Mar. 20, 2020 (KR) 10-2020-0034460

(51) Int. Cl. B32B 3/14; H10K 77/10; B32B 3/18; B32B 15/01; B32B 15/02; H04M 1/02

(52) U.S. Cl. CPC B32B 3/14; H10K 77/111; B32B 3/18; B32B 15/015; B32B 15/02; H04M 1/022; H04M 1/0269; H10K 2102/311

(57) ABSTRACT

The present disclosure relates to a folding plate and a method for manufacturing same, the folding plate, which is provided with a plurality of support plates and a plurality of flexible support plates connecting same, being used in multi-fold-type foldable phones to effectively impart heat-dissipation and support functions for a display.

### TECHNICAL FIELD

The present disclosure relates to a folding plate and a method of manufacturing the folding plate. More particularly, the present disclosure relates to a folding plate capable of finding application in a multi-step foldable phone that is foldable in a multi-stepped manner and supporting a display, and a method of manufacturing the folding plate.

### BACKGROUND ART

A foldable phone is manufactured using a flexible OLED display in such a manner that a screen thereof is foldable. The foldability of the foldable phone can increase portability thereof, and provides the advantage of possibly using a wider screen when the foldable phone is spread out.

A screen of the folder phone is folded or spread out using a hinge. When a folding plate is arranged on a rear surface of a display and is folded, a folding portion of the folding plate is fully folded up. When the folding plate is spread out, a flat wide screen appears without leaving boundary regions noticeable.

Importantly, the folding plate has to have such a degree of durability that it is capable of being tens of thousands of times folded and unfolded, and such a degree of mechanical durability that it is capable of supporting a display portion and protect the display portion from mechanical stress that can occur when the folding plate is folded.

In addition, there is a need for the folding plate to be manufactured in such a manner as to have a small thickness and to perform a heat dissipating function of dissipating heat occurring in the display.

### SUMMARY OF INVENTION

### Technical Problem

An object of the present disclosure is to provide a folding plate capable of finding application in a multi-step foldable phone in such a manner as to realize a wide display and supporting a display, and a method of manufacturing the folding plate. With this configuration, the folding phone can provide a high-performance effect of dissipating heat and contribute to reducing a thickness of the multi-step foldable phone.

### Solution to Problem

In order to accomplish the above-mentioned object, according to an aspect of the present disclosure, there is provided a folding plate including: a plurality of supporting plates arranged in a row; and a plurality of elastic supporting plates, each connecting the plurality of supporting plate to each other.

In the folding plate, the plurality of supporting plates and the plurality of elastic supporting plates each have an upper surface that may form the same plane and a lower surface that may form the same plane.

In the folding plate, a junction region may be formed on one lateral side of the supporting plate or both lateral sides thereof, and a junction portion corresponding to the junction region may be formed on both lateral sides of the elastic supporting plate. In the folding plate, the junction region and the junction portion may each have a stepped surface.

The folding plate may further include a brazing filler arranged on the junction region or the junction portion and joining the junction region and the junction portion to each other.

In the folding plate, the elastic supporting plate may include a mesh portion formed in a center portion of the elastic supporting plate, a mesh pattern being formed in a lengthwise direction in the mesh portion; and a supporting portion arranged on both lateral sides of the mesh portion, the junction portion being formed on the supporting portion.

In the folding plate, the plurality of elastic supporting plates may be arranged as to be vertically inverted to each other with at least one of the plurality of supporting plates in between. In the folding plate, the elastic supporting plate may be folded in such a manner that both sides of the broader of upper and lower surfaces thereof face each other.

According to another aspect of the present disclosure, there is provided a method of manufacturing a folding plate, the method may include steps of: preparing a plurality of supporting plates; preparing a plurality of elastic supporting plates; and connecting in a row the plurality of supporting plates to each other using the plurality of elastic supporting plates.

In the method, in the step of preparing the plurality of supporting plates, the supporting plate on whose one lateral side or whose both lateral sides a stepped junction region is formed may be prepared, and the junction region may be formed by half-etching the one lateral side of the supporting plate or the both sides thereof.

In the method, in the step of preparing the plurality of elastic supporting plates, a mesh portion in a center portion of the elastic supporting plate may be formed, a supporting portion on both lateral sides of the mesh portion may be arranged, the elastic supporting plate having the supporting portion on which a junction portion is formed may be prepared, the mesh portion may be formed by photo-etching in a lengthwise direction a center portion of the elastic supporting plate, and the junction portion may be formed, as a stepped surface corresponding to the stepped junction region, by half-etching an edge of the supporting portion.

In the method, the step of connecting in a row the plurality of supporting plates to each other may include steps of: arranging a brazing filler on the junction region or the junction portion; and joining, by brazing, the junction region and the junction portion to each other in a state where the junction region and the junction portion overlap each other.

In the method, in the step of joining, by brazing, the junction region and the junction portion to each other, the plurality of elastic supporting plates may be joined as to be vertically inverted to each other with at least one of the plurality of supporting plates in between.

In the method, in the step of preparing the plurality of supporting plates, the supporting plate may be prepared as a supporting plate made of copper (Cu) foil.

In the method, in the step of preparing the plurality of elastic supporting plates, the elastic supporting plate may be prepared as an elastic supporting plate made of stainless steel (SUS).

### Advantageous Effects of Invention

According to the present disclosure, a plurality of elastic supporting plate in each of which a mesh portion is formed connect a plurality of supporting plates to each other. Thus, a wide flat folding plate can be formed.

In addition, according to the present disclosure, plates made of a rigid metal material are used as the plurality of elastic supporting plates, and plates made of a metal material having a heat dissipating property are used as the plurality of supporting plates. Thus, in a case where the foldable plate finds application in a multi-step foldable phone, a function of supporting a display and a function of dissipating heat occurring in the display can be effectively performed.

In addition, the mesh portion is formed by etching a center portion of the elastic supporting plate having rigidity and thus has an elastic force that occurs with folding of the mesh portion. Thus, a display, when folded, is fully folded up, and when spread out, forms a flat plane without leaving a boundary region noticeable.

In addition, according to the present disclosure, a supporting portion is arranged on both lateral sides of the mesh portion and thus provides an elastic restoring force. Thus, the display, when unfolded in a folded state, can be flatly spread out without leaving the boundary region noticeable.

In addition, according to the present disclosure, the plurality of supporting plates and the plurality of elastic supporting plates have a stepped surface and are brazed thus the thickness of the multi-step foldable phone can be reduced and a durability thereof can be increased.

### BRIEF DESCRIPTION OF DRAWINGS

FIG. 1 is a view illustrating an example of a three-step foldable phone.

FIG. 2 is a plan view illustrating a folding plate according to an embodiment of the present disclosure.

FIG. 3 is a cross-sectional view illustrating the folding plate according to an embodiment of the present disclosure.

FIG. 4 is a cross-sectional view illustrating a method of manufacturing a folding plate according to an embodiment of the present disclosure.

FIG. 5 is a cross-sectional view illustrating a state where the folding plate in FIG. 3 is folded up.

### DESCRIPTION OF EMBODIMENTS

Embodiments of the present disclosure will be described in detail below with reference to the accompanying drawings.

A folding plate according to a first embodiment of the present disclosure may find application in multi-step foldable phones capable of being folded in a multi-stepped manner.

As an example, a shape of the folding plate according to the present disclosure that finds application in a three-step foldable phone, among the multi-step foldable phones, is described.

The folding plate according to the first embodiment of the present disclosure may be joined to a rear surface of a display of the three-step foldable phone and thus may perform a function of dissipating heat generated by the display and supporting the display. The three-step foldable phone is a foldable phone (smartphone) having a triple display in which three screens are folded into the shape of the letter “Z.”

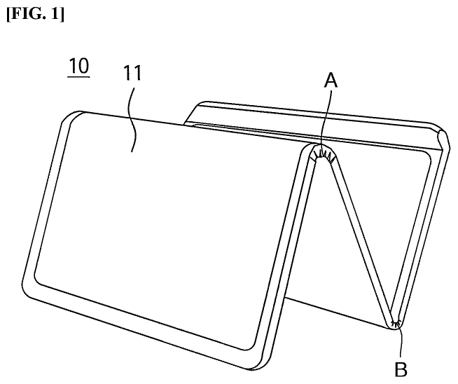

FIG. 1 illustrates a three-step foldable phone 10 in which a display 11 is folded around two vertical axes into the shape of the letter “Z.” One surface of the display 11 may be exposed to the outside in a state where the three-step foldable phone 10 is folded.

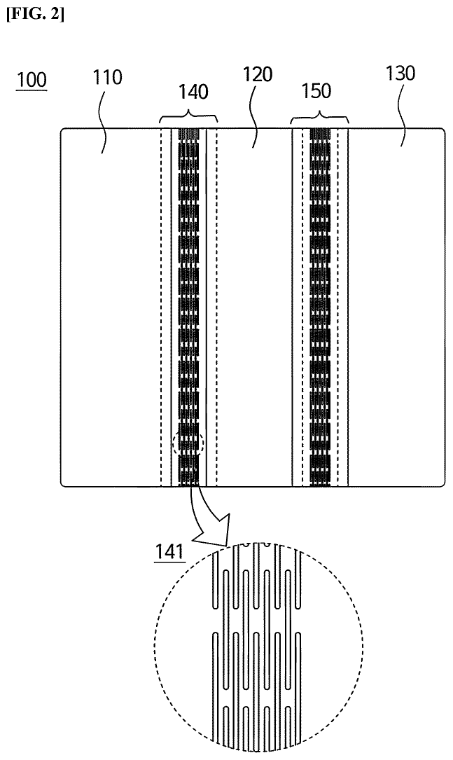

When the three-step foldable phone 10 is folded with a folding plate 100 (in FIG. 2) being arranged on a rear surface of the display 11, folding portions A and B may be fully folded up. When the three-step foldable phone 10 is spread out, a flat wide screen may appear without leaving boundary regions noticeable.

The folding plate according to the first embodiment of the present disclosure is described, taking as an example the shape of the three-step foldable phone illustrated in FIG. 1. It should be noted that, for the purpose of description, each of the constituent elements according to the first embodiment of the present disclosure may be illustrated in an exaggerated manner in the drawings.

FIG. 2 is a plan view illustrating a folding plate according to the first embodiment of the present disclosure.

As illustrated in FIG. 2, the folding plate 100 includes a plurality of supporting plates 110, 120, and 130 that are arranged in a row, and a plurality of elastic supporting plates 140 and 150 that connect the plurality of supporting plates 110, 120, and 130 to each other.

Specifically, the folding plate 100 includes a first supporting plate 110, a second supporting plate 120, a third supporting plate 130, a first elastic supporting plate 140, and a second elastic supporting plate 150. In the folding plate 100, the first elastic supporting plate 140 connects the first supporting plate 110 and the second supporting plate 120 to each other, and the second elastic supporting plate 150 connects the second supporting plate 120 and the third supporting plate 130 to each other.

Upper surfaces of the first supporting plate 110, the second supporting plate 120, the third supporting plate 130, the first elastic supporting plate 140, and the second elastic supporting plate that 150 that constitute the folding plate 100 may each form the same plane, and lower surfaces thereof may each form the same plane. Therefore, the folding plate 100 may have a more decreased thickness than when formed as multiple layers stacked on top of each other, and this may contribute to decreasing the thickness of the foldable phone.

The first supporting plate 110, the second supporting plate 120, and the third supporting plate 130 serve to perform a heat dissipating function and a supporting function. The first supporting plate 110, the second supporting plate 120, and the third supporting plate 130 are made of a metal material having a heat dissipation property. The first supporting plate 110, the second supporting plate 120, and the third supporting plate 130 may be made of Cu foil. Cu foil has the heat dissipating function and the supporting function.

The first elastic supporting plate 140 and the second elastic supporting plate 150 serve to perform the supporting function and a bending function. In order to perform the supporting function, the first elastic supporting plate 140 and the second elastic supporting plate 150 are made of a rigid metal material.

The first elastic supporting plate 140 and the second elastic supporting plate 150 may be made of a non-crystalline alloy or a stainless steel plate. For example, an amorphous alloy may be used as the non-crystalline alloy. The amorphous alloy has rigidity, but has a low etchability. In contract, the stainless steel plate has a high etchability, as well as rigidity. Therefore, the first elastic supporting plate 140 and the second elastic supporting plate 150 are made from the stainless steel plate. As an example, the stainless steel plate is made of SUS 304 stainless steel.

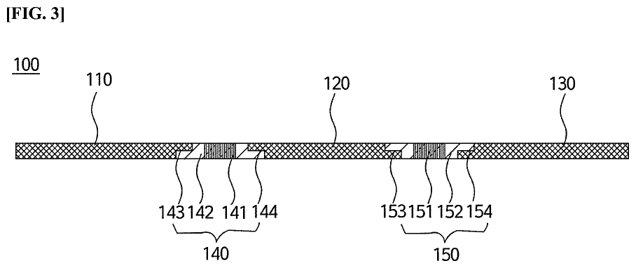

FIG. 3 is a cross-sectional view illustrating the folding plate according to the first embodiment of the present disclosure.

As illustrated in FIG. 3, in order to be bendable, the first elastic supporting plate 140 and the second elastic supporting plate 150 include mesh portions 141 and 151, respectively. Specifically, the first elastic supporting plate 140 includes the mesh portion 141, supporting portions 142, and junction portions 143 and 144, and the second elastic supporting plate 150 includes the mesh portion 151, supporting portions 152, and junction portions 153 and 154.

The mesh portions 141 and 151 are formed in the lengthwise direction in center portions, respectively, of the first elastic supporting plate 140 and the second elastic supporting plate 150. The supporting portions 142 are arranged on both lateral sides, respectively, of the mesh portions 141. The supporting portions 152 are arranged on both lateral sides, respectively, of the mesh portions 151. The junction portions 143 and 144 are formed on edges, respectively, of the supporting portion 142. The junction portions 153 and 154 are formed on edges, respectively, of the supporting portion 152. The mesh portions 141 and 151 serve to improve bendability of the elastic supporting plate 140 and bendability of the elastic supporting portion 150, respectively. The supporting portions 142 and 152 serve to improve restoring forces, respectively, of the elastic supporting plates 140 and 150. That is, the elastic supporting plates 140 and 150 are fully foldable with the mesh portions 141 and 151, respectively, and may be flatly unfolded with the supporting portions 142 and 152, respectively.

It is difficult to fold the first elastic supporting plate 140 and the second elastic supporting plate 150 that have rigidity. For this reason, the mesh portions 141 and 151 are formed in the center portions thereof, respectively. Accordingly, the first elastic supporting plate 140 and the second elastic supporting plate 150 may be provided with elastic forces, respectively, that occur with the folding of the mesh portions 141 and 151. In addition, the supporting portions 142 in the shape of a plate may be formed on both lateral sides, respectively, of the mesh portion 141, thereby providing restoring forces at the same time therefrom, and the supporting portions 152 in the shape of a plate may be formed on both lateral sides, respectively, of the mesh portion 151, thereby providing restoring forces at the same time therefrom. Therefore, the elastic supporting plates 140 and 150, when spread out, may each have a flat plane without leaving the boundary regions noticeable.

The junction portions 143 and 144 serve to join the elastic supporting plate 140 to the supporting plates 110 and 120. The junction portions 153 and 154 serve to join the elastic supporting plate 150 to the supporting plates 120 and 130. The junction portions 143 and 144 are referred to as a first junction portion 143 and a second junction portion 144, respectively, that are formed on both lateral sides, respectively, of the first elastic supporting plate 140. The junction portions 153 and 154 may be referred to as a third junction portion 153 and a fourth junction portion 154, respectively, that are formed on both lateral sides, respectively, of the second elastic supporting plate 150.

The mesh portions 141 and 151 are formed in the lengthwise direction in the center portions, respectively, of the elastic supporting plates 140 and 150. The mesh portions 141 and 151 each has a fixed width and are foldable in the widthwise direction. The mesh portions 141 and 151 may each serve as both a support body and a spring.

The first elastic supporting plate 140 may be formed between the first supporting plate 110 and the second supporting plate 120 of the folding plate 100 in such a manner as to join them to each other. The second elastic supporting plate 150 may be formed between the second supporting plate 120 and the third supporting plate 130 of the folding plate 100 in such a manner as to join them to each other.

A plurality of mesh portions 141 and 151 may be formed, by etching, in a large-sized metal plate having rigidity. Then, the resulting large-sized metal plate may be cut into a plurality of elastic supporting plates 140 and 150 to be used. Accordingly, unnecessary etching is not performed, and the cost for etching can be reduced.

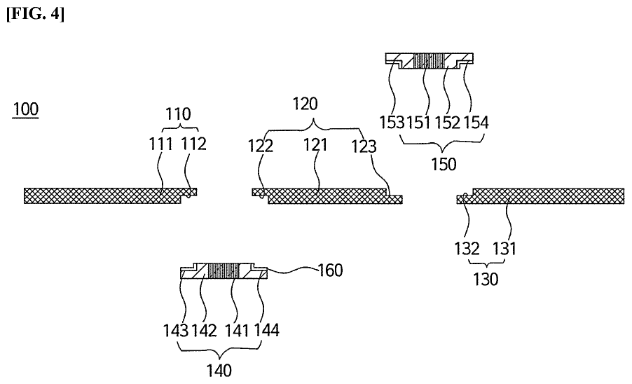

FIG. 4 is a cross-sectional view illustrating a method of manufacturing a folding plate according to an embodiment of the present disclosure.

As illustrated in FIG. 4, the first supporting plate 110 includes a first plate portion 111 and a first junction region 112. The first junction region 112 is formed on a bottom surface at one side of the first supporting plate 110. The second supporting plate 120 includes a second plate portion 121, a second junction region 122, and a third junction region 123. The second junction region 122 is formed on a bottom surface at one side of the second supporting plate 120, and the third junction region 123 is formed on an upper surface at the other side of the second supporting plate 120. The third supporting plate 130 includes a third plate portion 131 and a fourth junction region 132. The fourth junction region 132 is formed on an upper surface at one side of the third supporting plate 130.

The first junction portion 143 that is joined to the first junction region 112 of the first supporting plate 110 is formed on an upper surface at one side of the first elastic supporting plate 140. The second junction portion 144 that is joined to the second junction region 122 of the second supporting plate 120 is formed on an opposite upper surface at the other side of the first elastic supporting plate 140.

The third junction portion 153 that is joined to the third junction region 123 of the second supporting plate 120 is formed on a lower surface at one side of the second elastic supporting plate 150. The fourth junction portion 154 that is joined to the fourth junction region 132 of the third supporting plate 130 is formed on an opposite lower surface at the other side of the second elastic supporting plate 150.

In this configuration, the first elastic supporting plate 140 and the second elastic supporting plate 150 may be arranged as to be vertically inverted to each other with at least one of the plurality of supporting plates 110, 120, and 130 in between. In the folding plate according to an embodiment of the present disclosure, the first elastic supporting plate 140 and the second elastic supporting plate 150 may be arranged as to be vertically inverted to each other with the second supporting plate 120 in between, and may connect between the plurality of support plates 110, 120, and 130.

Specifically, the first junction portion 143 at one side of the first elastic supporting plate 140 may be joined to the first junction region 112 of the first supporting plate 110, and the second junction portion 144 at the other side of the first elastic supporting plate 140 may be joined to the second junction region 122 of the second supporting plate 120. Thus, the first supporting plate 110 and the second supporting plate 120 may be connected to each other.

The third junction portion 153 at one side of the second elastic supporting plate 150 may be joined to the third junction region 123 of the second supporting plate 120, and the fourth junction portion 154 at the other side of the second elastic supporting plate 150 may be joined to the fourth junction region 132 of the third supporting plate 130. Thus, the second supporting plate 120 and the third supporting plate 130 may be connected to each other.

The first to fourth junction regions 112, 122, 123, and 132, and the first to fourth junction portions 143, 144, 153, and 154 are stepped surfaces. Specifically, the first junction region 112 of the first supporting plate 110, the second junction region 122 and the third junction region 123 of the second supporting plate 120, and the fourth junction region 132 of the third supporting plate 130 are stepped surfaces formed by half-etching the first supporting plate 110, the second supporting plate 120, and the third supporting plate 130, respectively. The first junction portion 143 and the second junction portion 144 of the first elastic supporting plate 140 are stepped surfaces formed by half-etching both lateral sides, respectively, of the first elastic supporting plates 140. The third junction portion 153 and the fourth junction portion 154 of the second elastic supporting plate 150 are stepped surfaces formed by half-etching both lateral sides, respectively, of the second elastic supporting plate 150.

The first supporting plate 110, the second supporting plate 120, the third supporting plate 130, the first elastic supporting plate 140, and the second elastic supporting plate 150 have the same thickness. In addition, the first to fourth junction regions 112, 122, 123, and 132 and the first to fourth junction portions 143, 144, 153, and 154 are each thinned by half-etching in such manner as to have a thickness that is half a thickness of each of the plurality of supporting plates 110, 120, and 130 and the elastic supporting plates 140 and 150.

Therefore, respective joined portions of the first junction region 112 and the first junction portion 143, respective joined portions of the second junction region 122 and the second junction portion 144, respective joined portions of the third junction region 123 and the third junction portion 153, and respective joined portions of the fourth junction region 132 and the fourth junction portion 154 have the same thickness as the plurality of supporting plates 110, 120, and 130 and the plurality of elastic supporting plates 140 and 150. In addition, upper surfaces of the plurality of supporting plates 110, 120, and 130 and the plurality of elastic supporting plates 140 and 150 may form the same plane with respect to each other, and lower surfaces thereof may also form the same plane with respect to each other.

The mesh portions 141 and 151 may each be formed in a mesh pattern in which a plurality of lines long in the upward-downward direction intersect. The mesh portions 141 and 151 have to have such a degree of durability that they are capable of being tens of thousands of times folded and unfolded. Therefore, in mesh patterns of the mesh portions 141 and 151, the plurality of lines long in the upward-downward direction are arranged in such a manner as to be spaced away from each other in a transverse direction, but in such a manner as to partly intersect each other in an overlapping fashion. Thus, the durability can be increased.

The mesh portions 141 and 151 are formed by photo-etching the center portions, respectively, of the elastic supporting plates 140 and 150. When the mesh portions 141 and 151 are formed by perforating by a press, the mesh patterns thereof are not precise. When the mesh patterns are not precise, it is difficult to form the mesh portions that have a desired elastic force.

The elastic supporting plates 140 and 150 may be made of SUS 304 stainless steel. The elastic supporting plates 140 and 150, when made of SUS 304, has a high etchability and thus may form a mesh pattern in a desired shape. SUS 304 stainless steel may be used with a thickness of 0.1 mm to 0.5 mm (100 μm to 150 μm).

In the mesh patterns of the mesh portions 141 and 151, the plurality of lines each have a line-width L of 80 μm to 120 μm, and a distance S between each of the plurality of lines is 100 μm to 300 μm. As one practical example of the present disclosure, in the mesh patterns of the mesh portions 141 and 151, the plurality of lines each have the line-width L of 100 μm, and the distance S between each of the plurality of lines is 200 μm. In the mesh patterns of the mesh portions 141 and 151, it is preferable that the plurality of lines each have the line-width L of 100 μm.

A brazing filler 160 may be arranged in the first to fourth junction regions 112, 122, 123, and 132 or the first to fourth junction portions 143, 144, 153, and 154. The brazing filler 160 may be formed as a multi-layered thin film. The multi-layered thin film serves to compensate for insufficient function and increase an adhesive power.

The brazing filler 160 may be a brazing alloy layer and may include an Ag layer and a Cu layer. The brazing filler 160 may further include a seed layer for increasing a force for attaching the brazing alloy layer and a base metal to each other. Examples of the base metal include the first elastic supporting plate 140, the second elastic supporting plate 150, the first supporting plate 110, the second supporting plate 120, and the third supporting plate 130.

The seed layer may contain at least one of copper (Cu) and titanium (Ti). The seed layer may include a first seed layer and a second seed layer. In this case, the first seed layer may be formed of titanium (Ti), and the second seed layer may be formed of copper Cu.

The brazing filler 160 may be used to join, by brazing, the supporting plates 110, 120, and 130 made of copper (Cu), a metal having a high melting point, to the elastic supporting plates 140 and 150 made of stainless steel. The brazing filler 160 may have a thickness of 5 μm to 10 μm. For example, the brazing filler 160 may include an Ag layer and a Cu layer formed on an upper layer of the Ag layer and may have a thickness of 5 μm. Alternatively, the brazing filler 160 may include the Ag layer, the Cu layer formed on the upper surface of the Ag layer, and an Ag layer formed on an upper surface of the Cu layer and may have a thickness of 5 μm.

A Ti layer may be formed in such a manner as to have a thickness of 0.1 μm to 0.2 μm. The Cu layer may be formed in such a manner as to have a thickness of 0.2 μm to 0.5 μm. The Ag layer formed on top of the Cu layer may be formed in such a manner as to have a thickness of 1.5 μm. The Cu layer formed on top of the Ag layer may be formed in such a manner as to have a thickness of 1.5 μm. The Ag layer formed on top of the Cu layer may be formed in such a manner as to have a thickness of 2 μm.

Alternatively, the Ti layer may be formed in such a manner as to have a thickness of 0.1 μm to 0.2 μm, the Cu layer may be formed in such a manner as to have a thickness of 0.2 μm to 0.5 μm, the Ag layer formed on top of the Cu layer may be formed in such a manner as to have a thickness of 1.5 μm, the Cu layer formed on top of the Ag layer may be formed in such a manner as to have a thickness of 2 μm, and the Ag layer formed on top of the Cu layer may be formed in such a manner as to have a thickness of 1.5 μm.

The stepped junction regions 112 and 122 may be formed on opposing lateral sides, respectively, of the supporting plate 110 and 120. The stepped junction regions 123 and 132 may be formed on opposing lateral sides, respectively, of the supporting plate 120 and 130. The stepped junction portions 143 and 144 may be formed on both lateral sides, respectively, of the elastic supporting plate 140. The stepped junction portions 153 and 154 may be formed on both lateral sides, respectively, of the elastic supporting plate 150. The junction portions 143 and 144 may be joined, by brazing, to the junction regions 112 and 122, respectively. The junction portions 153 and 154 may be joined, by brazing, to the junction regions 123 and 132, respectively. Because of this, the folding plate 100 according to the first embodiment of the present disclosure may be integrally formed thinly in such a manner as to have a minimum thickness of 0.1 mm. A thickness of the folding plate 100 may be suitably designed, considering a thickness of the display 11.

In addition, the folding plate 100 is formed by joining a copper plate to both sides of a plate made of a stainless material. This has the excellent effect of dissipating heat. Moreover, the advantage of possibly further simplifying a manufacturing process can be provided. A temperature when joining is performed by brazing may range 850° C. to 950° C.

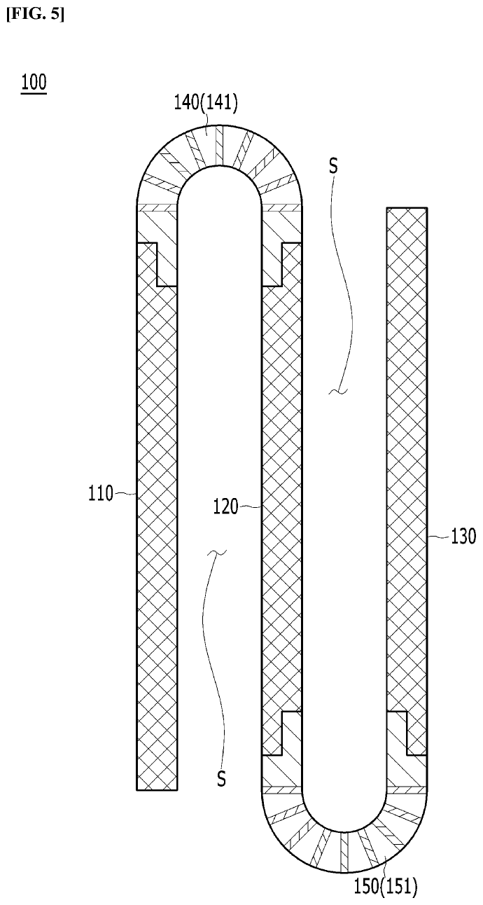

FIG. 5 is a cross-sectional view illustrating a state where the folding plate in FIG. 3 is folded. FIG. 5 illustrates in an exaggerated manner the state where the folding plate 100 is folded. For convenience, an illustration of the display 11 (in FIG. 1) that is folded along with the folding plate 100 is omitted.

As illustrated in FIG. 5, the mesh portion 141 of the first elastic supporting plate 140 is folded outward, and thus the first supporting plate 110 and the second supporting plate 120 of the folding plate 100 may face each other with a space S1 in between, In addition, the mesh portion 151 of the second elastic supporting plate 150 is folded inward, and thus the second supporting plate 120 and the third supporting plate 130 may face each other with a space S2 in between.

In this manner, since the mesh portions 141 and 151 have the elastic forces that occur with the folding thereof, the folding plate 100 may be fully folded outward and inward, respectively. In addition, the folding plate 100, when spread out in a folded state, may be flatly unfolded by the restoring forces provided by the supporting portions 142 and 152 in the shape of a plate without leaving the boundary regions noticeable (refer to FIG. 3).

In addition, the first elastic supporting plate 140 may be folded in such a manner that both sides of the broader of upper and lower surfaces of the first elastic supporting plate 140 face each other. In the same manner, the second elastic supporting plate 150 may be folded in such a manner that both sides of the broader of upper and lower surfaces of the second elastic supporting plate 150 face each other. The supporting portions 142 arranged on both lateral sides, respectively, of the mesh portion 141, and the supporting portions 152 arranged on both lateral sides, respectively, of the mesh portion 151 serve to provide elastic restoring forces. The broader of the upper and lower surfaces of the elastic supporting plate 140 corresponds to a portion of the supporting portion 142 that is formed to have a greater area. The broader of the upper and lower surfaces of the elastic supporting plate 150 corresponds to a portion of the supporting portion 152 that is formed to have a greater area. In this manner, when the portion of the supporting portion 142 that is formed to have a greater area is folded in such a manner that both sides thereof face each other, in a case where the supporting portion 142 is spread out, the elastic restoring force is easier to provide than when the portion of the supporting portion 142 that is formed to have a smaller area is folded. This is true for the supporting portion 152. The display 11, when spread out in the folded state, may be flatly unfolded by the elastic restoring forces of the supporting portions 142 and 152, without leaving the boundary regions noticeable.

A method of manufacturing a folding plate according to a second embodiment of the present disclosure may include: a step of preparing a plurality of supporting plates 110, 120, and 130; a step of preparing a plurality of elastic supporting plates 140 and 150; and a step of connecting the plurality of supporting plates 110, 120, and 130 in a row using the plurality of elastic supporting plates 140 and 150.

Specifically, the method of manufacturing a folding plate may include: a step of preparing a first supporting plate 110, a second supporting plate 120, and a third supporting plate 130 on which junction regions 112, 122, 123, and 132, respectively, are formed; a step of forming junction portions 143, 144, 153, and 154 that correspond to the junction regions 112, 122, 123, and 132, respectively, and preparing a first elastic supporting plate 140 and a second elastic supporting plate 150, mesh portions 141 and 151 being formed in a lengthwise direction on center portions, respectively, of the first elastic supporting plate 140 and the second elastic supporting plate 150; a step of arranging a brazing filler 160 on the junction regions 112, 122, 123, and 132 or junction portions 143, 144, 153, and 154; a step of arranging the first elastic supporting plate 140 between the first supporting plate 110 and the second supporting plate 120 and arranging the second elastic supporting plate 150 between the second supporting plate 120 and the third supporting plate 130 in such a manner that the junction regions 112, 122, 123, and 132 overlap the junction portions 143, 144, 153, and 154, respectively; and a step of joining, by brazing, the junction regions 112, 122, 123, and 132 and the junction portions 143, 144, 153, and 154, respectively.

In the step of preparing the first supporting plate, the second supporting plate, and the third supporting plate, the stepped junction region 112 may be formed by half-etching one lateral side of the first supporting plate 110, the stepped junction regions 122 and 123 by half-etching both lateral sides, respectively, of the second supporting plate 120, and the stepped junction region 132 by half-etching one lateral side of the third supporting plate 130.

In the step of preparing the first elastic supporting plate and the second elastic supporting plate, the junction portions 143 and 144 may be formed, as stepped surfaces, by half-etching edges, respectively, of supporting portions 142 arranged on both lateral sides, respectively, of the mesh portion 141. The junction portions 153 and 154 may be formed, as stepped surfaces, by half-etching edges, respectively, of supporting portions 152 arranged on both lateral sides, respectively, of the mesh portion 151. In addition, the mesh portions 141 and 151 may be formed by photo-etching center portions, respectively, of the first elastic supporting plate 140 and the second elastic supporting plate 150.

When the mesh portions 141 and 151 are formed by perforating by a press, a mesh pattern is difficult to precisely form, and thus is formed by photo-etching. In a case where the mesh portions 141 and 151 are formed by the photo-etching, the mesh pattern may be precisely formed. As illustrated in FIG. 2, the mesh pattern is formed by arranging the plurality of lines long in the upward-downward direction in such a manner as to intersect each other.

In the step of preparing the first supporting plate, the second supporting plate, and the third supporting plate, the first supporting plate 110, the second supporting plate 120, and the third supporting plate 130 may be prepared as supporting plates made of Cu foil.

In the step of preparing the first elastic supporting plate and the second elastic supporting plate, the first elastic supporting plate 140 and the second elastic supporting plate 150 may be prepared as elastic supporting plates made of stainless steel (SUS).

A stainless steel (SUS grade stainless steel) plate has rigidity and thus is readily used as a supporting plate for supporting the display, but has a low-level heat dissipation property. Therefore, the first supporting plate 110, the second supporting plate 120, and the third supporting plate 130 are made of copper foil, and the heat dissipation properties thereof may be enhanced. The elastic supporting plates 140 and 150 may be prepared as elastic supporting plates made of SUS 304 stainless steel.

The brazing filler 160 may include an Ag layer and a Cu layer.

The brazing filler 160 may be arranged, in the form of Bag 8 foil, plating filler metal, or paste, on the junction region 112 of the supporting plate 110, the junction regions 122 and 123 of the supporting plate 120, and the junction region 132 of the supporting plate 130, or the junction portions 143 and 144 of the elastic supporting plate 140 and the junction portions 153 and 154 of the elastic supporting plate 150.

In the step of joining, by brazing, the junction regions 112, 122, 123, and 132 and the junction portions 143, 144, 153, and 154, respectively, the first elastic supporting plate 140 and the second elastic supporting plate 150 may be arranged as to be vertically inverted to each other with one of the plurality of supporting plates 110, 120, and 130 in between, and may connect between the plurality of support plates 110, 120, and 130. Specifically, the first elastic supporting plate 140 and the second elastic supporting plate 150 may be joined as to be vertically inverted to each other with the second supporting plate 120 in between, and may connect the supporting plates 110, 120, and 130.

The reason for arranging the elastic supporting plates 140 and 150 in this manner is to arrange a flat surface of the elastic supporting plates 140 and 150 on which the junction portions 153 and 154 are not formed and which has a broader area, at a position for inward folding, that is, at a position for positioning both sides of the flat surface in such a manner as to face each other when the elastic supporting plates 140 and 150 is folded. When the portion of the elastic supporting plate 140 that has a greater area, as described above, is positioned at the position for inward folding, it is easier for the supporting portions 142 arranged on both lateral sides, respectively, of the mesh portion 141 to provide the elastic restoring force. When the portion of the elastic supporting plate 150 that has a greater area, as described above, is positioned at the position for inward folding, it is easier for the supporting portions 152 arranged on both lateral sides, respectively, of the mesh portion 151 to provide the elastic restoring force.

The junction regions 112, 122, 123, and 132 and the junction portions 143, 144, 153, and 154 are formed as stepped surfaces. Accordingly, the elastic supporting plate 140 is joined to each of the supporting plates 110 and 120 by bringing the stepped surfaces into contact with each other, and the elastic supporting plate 150 is joined to each of the supporting plates 120 and 130 by bringing the stepped surfaces into contact with each other. Accordingly, the effect of increasing respective junction areas of the elastic supporting plates 140 and 150 and the supporting plates 110, 120, and 130 and thus enhancing a joining strength is provided. The stepped surface, when formed by flattening by a press, has a low level of flatness, and thus the joining strength is decreased. For this reason, the stepped surface is formed by half-etching. The etching improves the level of flatness and contributes to increasing the joining strength.

In the step of performing joining by brazing, a temperature for joining by brazing may range from 850° C. to 950° C.

In the folding plate 100 manufactured by the method according to an embodiment of the present disclosure, upper surfaces of the elastic supporting plates 140 and 150 and the supporting plates 110, 120, and 130 form the same plane, and lower surfaces thereof form the same plane. The elastic supporting plates 140 and 150 and the supporting plates 110, 120, and 130 may each have a thickness of 0.1 mm to 0.15 mm (100 μm to 150 μm). As an example, when the elastic supporting plates 140 and 150 and the supporting plates 110, 120, and 130 each have a thickness of 150 μm, the junction regions 112, 122, 123, and 132 and the junction portions 143, 144, 153, and 154, which are formed by half-etching, each have a thickness of 75 μm.

In addition, the supporting plates 110, 120, and 130 joined to both lateral sides, respectively, of the elastic supporting plates 140 and 150 are made of a heat dissipating material. Thus, the folding plate 100 has a high-level heat dissipating property.

In addition, the elastic supporting plates 140 and 150 are made of a material having rigidity. The elastic supporting plates 140 and 150 include the mesh portions 141 and 151, respectively, in the center portions thereof, and thus each have the elastic forces that occur with the folding thereof. Accordingly, the folding plate 100, when bent, may be fully folded up, and when spread out, may have a flat surface without leaving the boundary regions noticeable.

In addition, the mesh portions 141 and 151 are formed in a mesh pattern in the folding plate 100. In the mesh pattern, the plurality of lines long in the upward-downward direction are arranged in such a manner as to intersect. Thus, the durability of the mesh portions can be secured.

The folding plate described above finds application in the three-step foldable phone that has the triple display in which three screens are folded into the shape of the letter “Z,” and thus may support the display.

The folding plate 100 described above is attached to the rear surface of the display 11. While the mesh portions 141 and 151 of the folding plate 100 are folded, the display is folded in an elastically transformed manner. When the display is spread out, the supporting portions 142 arranged on both lateral sides, respectively, of the mesh portion 141 and the supporting portions 152 arranged on both lateral sides, respectively, of the mesh portion 151 provide the elastic restoring forces. Thus, the display may be flatly unfolded without leaving the boundary regions noticeable.

In addition, in the folding plate 100, the first supporting plate 110 and the second supporting plate 120 joined to both lateral sides, respectively, of the first elastic supporting plate 140, and the second supporting plate 120 and the third supporting plate 130 joined to both lateral sides, respectively, of the second elastic supporting plate 150 are made of a heat dissipating material. Thus, heat occurring in the display may be quickly dissipated.

The folding plate 100 may find application in a four-step or five-step foldable phone, depending on the number of supporting plates and the number of elastic supporting plates connecting the supporting plates to each other.

The preferred embodiments of the present disclosure are described above with reference to the drawings. Specific terms are used throughout the specification for the purpose of describing the embodiments of the present disclosure, without any limitation being imposed on the meanings thereof and the scope of the present disclosure that is defined by the claims. From the present specification, it would be understandable to a person of ordinary skill in the art that various modifications to the embodiments and other equivalent embodiments are possible. Therefore, the proper technical scope of the present disclosure should be determined by the technical idea that is defined in the following claims.

1. A folding plate comprising:
a plurality of supporting plates arranged in a row; and
a plurality of elastic supporting plates, each connecting the plurality of supporting plates to each other.

2. The folding plate of claim 1, wherein upper surfaces of the plurality of supporting plates and the plurality of elastic supporting plates forms a same plane and lower surfaces of the plurality of supporting plates and the plurality of elastic supporting plates forms a same plane.

3. The folding plate of claim 1, wherein a junction region is formed on one lateral side of the supporting plate or both lateral sides thereof, and a junction portion corresponding to the junction region is formed on both lateral sides of the elastic supporting plate.

4. The folding plate of claim 3, wherein the junction region and the junction portion each have a stepped surface.

5. The folding plate of claim 3, further comprising:
a brazing filler arranged on the junction region or the junction portion and joining the junction region and the junction portion to each other.

6. The folding plate of claim 3, wherein the elastic supporting plate comprises:
a mesh portion formed in a center portion of the elastic supporting plate, a mesh pattern being formed in a lengthwise direction in the mesh portion; and
a supporting portion arranged on both lateral sides of the mesh portion, the junction portion being formed on the supporting portion.

7. The folding plate of claim 1, wherein the plurality of elastic supporting plates are arranged as to be vertically inverted to each other with at least one of the plurality of supporting plates in between.

8. The folding plate of claim 1, wherein the elastic supporting plate is folded in such a manner that both sides of the broader of upper and lower surfaces thereof face each other.

9. A method of manufacturing a folding plate, the method comprising steps of:
preparing a plurality of supporting plates;
preparing a plurality of elastic supporting plates; and
connecting in a row the plurality of supporting plates to each other using the plurality of elastic supporting plates.

10. The method of claim 9, wherein in the step of preparing the plurality of supporting plates, the supporting plate on whose one lateral side or whose both lateral sides a stepped junction region is formed is prepared, and
wherein the junction region is formed by half-etching the one lateral side of the supporting plate or the both sides thereof.

11. The method of claim 10, wherein in the step of preparing the plurality of elastic supporting plates, a mesh portion in a center portion of the elastic supporting plate is formed, a supporting portion on both lateral sides of the mesh portion is arranged, the elastic supporting plate having the supporting portion on which a junction portion is formed is prepared, the mesh portion is formed by photo-etching in a lengthwise direction a center portion of the elastic supporting plate, and the junction portion is formed, as a stepped surface corresponding to the junction region, by half-etching an edge of the supporting portion.

12. The method of claim 11, the step of connecting in a row the plurality of supporting plates to each other comprises steps of:
arranging a brazing filler on the junction region or the junction portion; and
joining, by brazing, the junction region and the junction portion to each other in a state where the junction region and the junction portion overlap each other.

13. The method of claim 12, wherein in the step of joining, by brazing, the junction region and the junction portion to each other, the plurality of elastic supporting plates are joined as to be vertically inverted to each other with at least one of the plurality of supporting plates in between.

14. The method of claim 9, wherein in the step of preparing the plurality of supporting plates, the supporting plate is prepared as a supporting plate made of copper (Cu) foil.

15. The method of claim 9, wherein in the step of preparing the plurality of elastic supporting plates, the elastic supporting plate is prepared as an elastic supporting plate made of stainless steel (SUS).
